(19) United States
(12) Patent Application Publication
(10) Pub. No.: US 2020/0302626 A1
(43) Pub. Date: Sep. 24, 2020

(54) OPTICAL DEVICE, DETECTION DEVICE, AND ELECTRONIC APPARATUS

(71) Applicants: Toshiyuki IKEOH, Duesseldorf (DE); Takumi SATOH, Miyagi (JP)

(72) Inventors: Toshiyuki IKEOH, Duesseldorf (DE); Takumi SATOH, Miyagi (JP)

(21) Appl. No.: 16/799,984

(22) Filed: Feb. 25, 2020

(30) Foreign Application Priority Data
Mar. 20, 2019 (JP) 2019-052673

(51) Int. Cl. G06T 7/593; G02B 3/00; H01S 5/42; H01S 5/022; H01S 5/042; H04N 5/225; G06K 9/00; G06T 7/521; H04N 13/239; H04N 13/254

(52) U.S. Cl. CPC G06T 7/593; G02B 3/0037; H01S 5/423; H01S 5/02288; H01S 5/04256; G06T 2207/10028; G06K 9/00201; G06T 7/521; H04N 13/239; H04N 13/254; G06T 2207/10012; H04N 5/2254

(57) ABSTRACT

An optical device includes an array light source including a plurality of light emitting elements and configured to emit mutually incoherent light; and a lens array including a plurality of lenses and configured to transmit light emitted from the light emitting elements. Light emitted from one light emitting element of the plurality of light emitting elements of the array light source is incident on at least two lenses of the plurality of lenses of the lens array.

### CROSS-REFERENCE TO RELATED APPLICATIONS

This patent application is based on and claims priority pursuant to 35 U.S.C. § 119(a) to Japanese Patent Application No. 2019-052673, filed on Mar. 20, 2019, in the Japan Patent Office, the entire disclosure of which is hereby incorporated by reference herein.

### BACKGROUND

### Technical Field

The present disclosure relates to an optical device, a detection device, and an electronic apparatus.

### Description of the Related Art

A stereo imaging method using two or more cameras is known as a method for acquiring a three-dimensional shape of an object, distance information to an object, depth mapping, or the like. The stereo imaging method finds a corresponding point indicating, when one of the cameras captures an image and another one of the cameras captures an image, which coordinates in the image of the other camera correspond to the coordinates of a specific pixel on the image of the one camera, and performs measurement using a shift amount of the coordinates. Thus, it is difficult to determine a corresponding point between cameras for an object having poor characteristics for identification (shading, shape, color), such as a monochromatic wall or a human face.

### SUMMARY

An optical device according to an embodiment of the present disclosure includes an array light source including a plurality of light emitting elements and configured to emit mutually incoherent light; and a lens array including a plurality of lenses and configured to transmit light emitted from the light emitting elements. Light emitted from one of the plurality of light emitting elements of the array light source is incident on at least two of the plurality of lenses of the lens array.

### BRIEF DESCRIPTION OF THE SEVERAL VIEWS OF THE DRAWINGS

A more complete appreciation of the disclosure and many of the attendant advantages and features thereof can be readily obtained and understood from the following detailed description with reference to the accompanying drawings, wherein:

FIG. 1 schematically illustrates an object recognition apparatus which is an embodiment of a detection device including a pattern light projector (optical device) to which the disclosure is applied;

FIG. 2 illustrates a state in which the pattern light projector irradiates an object with a stripe pattern;

FIGS. 3A, 3B, 3C, and 3D each illustrates corresponding-point recognition of two cameras in the case of irradiation with the stripe pattern;

FIGS. 4A and 4B schematically illustrate the pattern light projector, FIG. 4A illustrating a configuration including a microlens array for light projection, FIG. 4B illustrating a configuration including an optical element in addition to the microlens array;

FIG. 5 illustrates a case where light emitted from one light emitting element is incident on one microlens;

FIG. 6 illustrates a case where light emitted from one light emitting element is incident on a plurality of microlenses;

FIG. 7 illustrates a case where light emitted from one light emitting element is transmitted through a portion between a plurality of microlenses;

FIGS. 8A and 8B each illustrate an example configuration of a microlens array that inhibits light from being transmitted through a portion between a plurality of microlenses,

FIG. 8A illustrating a configuration in which a gap is not provided between microlenses, FIG. 8B illustrating a configuration in which a light shielding member is provided between microlenses;

FIG. 9 illustrates an emission pattern when light emitted from one light emitting element is incident on a plurality of microlenses in a square arrangement;

FIG. 10 illustrates an emission pattern when light emitted from one light emitting element is incident on a plurality of microlenses in a hexagonal filling arrangement;

FIG. 11 illustrates an emission pattern when light emitted from one light emitting element is incident on a plurality of microlenses in a rectangular arrangement;

FIG. 12 illustrates an emission pattern when beams of light emitted from two light emitting elements are incident on a plurality of microlenses;

FIG. 13 illustrates an emission pattern when beams of light emitted from an array light source including a plurality of unevenly arranged light emitting elements are incident on a plurality of microlenses;

FIG. 14 illustrates an emission pattern when an array light source and a microlens array are inclined with respect to a pixel arrangement direction of an image sensor;

FIGS. 15A to 15C illustrate setting of emission intensities of a plurality of light emitting elements of an array light source, FIG. 15A illustrating emitted pattern light, FIG. 15B illustrating an intensity distribution of pattern light with a constant emission intensity, FIG. 15C illustrating an intensity distribution of pattern light with different emission intensities;

FIGS. 16A and 16B illustrate an example configuration in which light emitting elements of an array light source have different emission intensities, FIG. 16A illustrating an arrangement of electrodes of the array light source, FIG. 16B illustrating a relationship between an amount of electric current to be supplied to an electrode and an emission amount;

FIGS. 17A and 17B illustrate an example configuration in which light emitting elements of an array light source have different emission intensities, FIG. 17A illustrating emission areas of respective light emitting elements of the array light source, FIG. 17B illustrating a relationship among an emission area, a current amount, and an emission amount;

FIGS. 18A and 18B illustrate an example configuration in which light emitting elements of an array light source have different emission intensities, FIG. 18A illustrating an array light source in front view, FIG. 18B illustrating a state in which beams of light emitted from two light emitting elements at corresponding positions are superposed on each other;

FIGS. 19A and 19B illustrate an example configuration in which a plurality of light emitting elements of an array light source have different emission intensities, FIG. 19A illustrating the array light source in front view, FIG. 19B illustrating emitted pattern light;

FIG. 20 illustrates an example in which a detection device including a pattern light projector is applied to a movable apparatus;

FIG. 21 illustrates an example in which a detection device including a pattern light projector is applied to a portable information terminal;

FIG. 22 illustrates an example in which a detection device including a pattern light projector is applied to a driving assistance system for a mobile body;

FIG. 23 illustrates an example in which a detection device including a pattern light projector is applied to an autonomous traveling system of a mobile body; and

FIG. 24 illustrates an example in which a detection device including a pattern light projector is applied to a shaping apparatus.

The accompanying drawings are intended to depict embodiments of the present invention and should not be interpreted to limit the scope thereof. The accompanying drawings are not to be considered as drawn to scale unless explicitly noted.

### DETAILED DESCRIPTION

The terminology used herein is for the purpose of describing particular embodiments only and is not intended to be limiting of the present invention. As used herein, the singular forms “a”, “an” and “the” are intended to include the plural forms as well, unless the context clearly indicates otherwise.

In describing embodiments illustrated in the drawings, specific terminology is employed for the sake of clarity. However, the disclosure of this specification is not intended to be limited to the specific terminology so selected and it is to be understood that each specific element includes all technical equivalents that have a similar function, operate in a similar manner, and achieve a similar result.

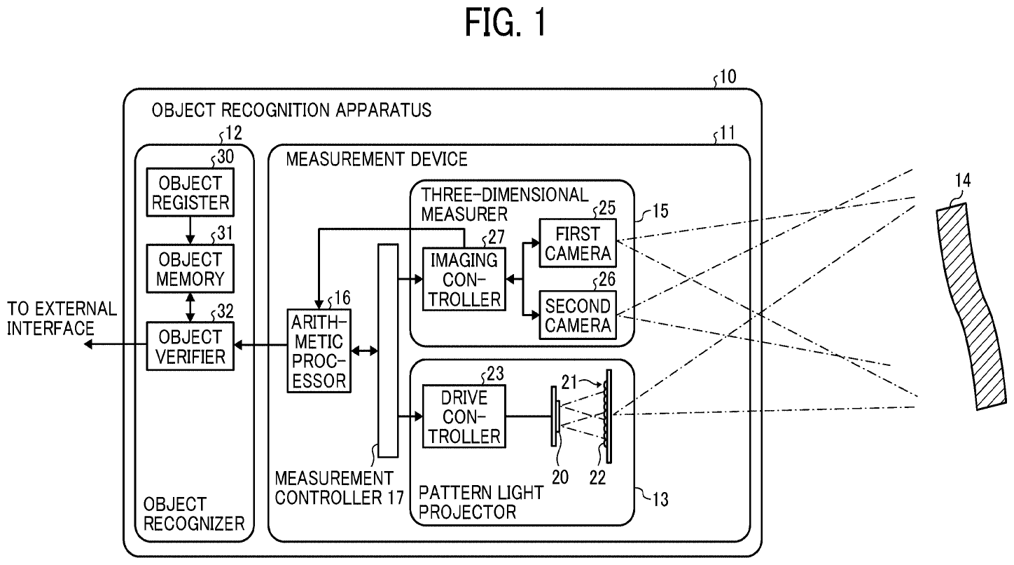

An embodiment to which the present disclosure is applied is described below referring to the drawings. FIG. 1 illustrates an outline of an object recognition apparatus 10 for recognizing a three-dimensional shape of an object. The object recognition apparatus 10 includes a measurement device 11 and an object recognizer 12.

The measurement device 11 irradiates an object 14 with pattern light from a pattern light projector (optical device) 13, image captures light reflected by the optical device 14 using a three-dimensional measurer 15, and performs arithmetic processing using an arithmetic processor 16 based on the captured image to acquire three-dimensional distance information.

More specifically, the pattern light projector 13 includes an array light source 20 including a plurality of (at least two) light emitting elements, a microlens array 21 including a plurality of microlenses 22 in a predetermined arrangement, and a drive controller 23 that controls emission (emission timing, emission duration, emission amount, and the like) of the array light source 20. The pattern light projector 13 irradiates the object 14 with pattern light (details will be described later).

The three-dimensional measurer 15 is a stereo camera using parallax, and includes a first camera 25 and a second camera 26, as an imager. Imaging conditions such as the exposure duration, shutter speed, and frame rate of each of the first camera 25 and the second camera 26 are controlled by an imaging controller 27 to perform image capturing. Each of the first camera 25 and the second camera 26 includes an image sensor (not illustrated) and a light receiving optical system (not illustrated) that guides light reflected by a subject to the image sensor to form a subject image on a light receiving surface. The image sensor has a plurality of pixels arranged on the light receiving surface, and each pixel includes a photoelectric conversion element. The light received by the image sensor (subject image) is photoelectrically converted, and is transmitted as an electrical signal to the arithmetic processor 16.

The pattern light projector 13 and the three-dimensional measurer 15 are controlled by a measurement controller 17. The arithmetic processor 16, in a state in which the pattern light projector 13 irradiates the object 14 with the pattern light, calculates parallax from a parallax image captured by the three-dimensional measurer 15 (an image captured by the first camera 25 and an image captured by the second camera 26), and acquires three-dimensional information (distance, shape, and so forth) of the object 14.

The object recognizer 12 includes an object register 30 that registers information on an object to be recognized, an object memory 31 that stores the registered information on the object, and an object verifier 32 that verifies the stored information on the object against the information on the object 14 measured by the measurement device 11. The object verifier 32 compares and verifies the three-dimensional information on the object 14 measured by the measurement device 11 against the object information stored (registered) in the object memory 31 to recognize the characteristics of the object 14. The information obtained by the object recognizer 12 is transmitted to an external interface.

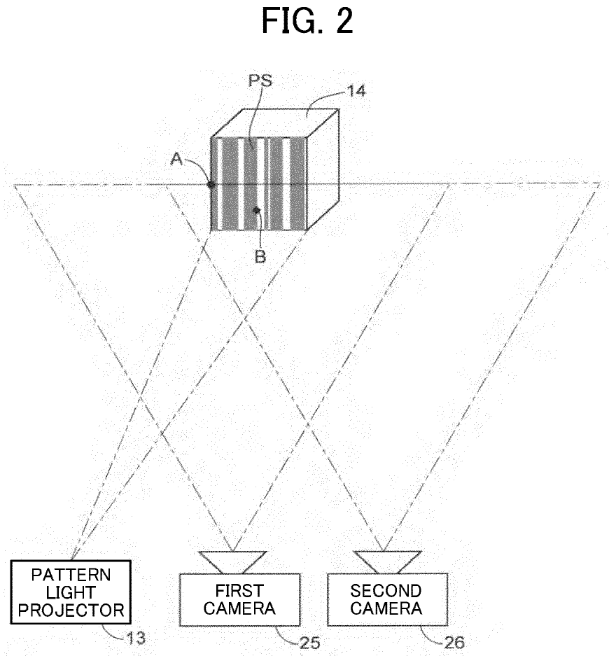

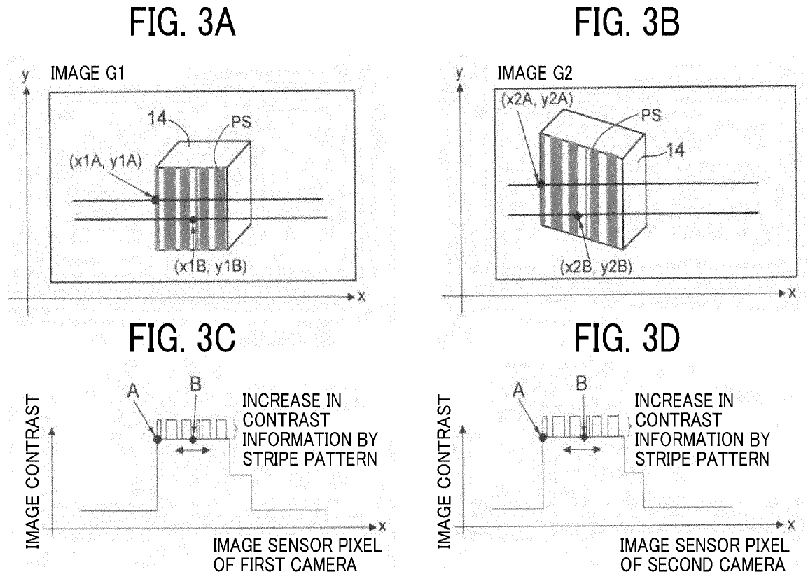

FIGS. 2 and 3 illustrate acquisition of three-dimensional information on an object 14 by the three-dimensional measurer 15. As illustrated in FIG. 2, the three-dimensional measurer 15 acquires an image from each of the first camera 25 and the second camera 26 arranged at a predetermined interval, and measures a three-dimensional shape by using parallax information on the two images. More specifically, the three-dimensional measurer 15 determines which coordinates in the image acquired by the second camera 26 correspond to the coordinates of a pixel at a certain point on the image acquired by the first camera 25, and calculates depth information based on triangulation using a shift amount of the coordinates.

For example, as a result that the three-dimensional measurer 15 image captures a certain cube serving as an object 14, as illustrated in FIGS. 3A, 3B, 3C, and 3D, an image G1 captured by the first camera 25 and an image G2 captured by the second camera 26 are obtained. At this time, a point A on an edge of the cube in the image G1 is located at the coordinates (x1A, y1A) of a pixel on the image sensor of the first camera 25. In the image G2, the point A of the object is positioned at the coordinates (x2A, y2A) of a pixel on the image sensor of the second camera 26 in accordance with the distance by which the first camera 25 and the second camera 26 are apart. Using the coordinates of the two pixels and the distance between the first camera 25 and the second camera 26, the depth of the object 14 can be measured based on triangulation, and the three-dimensional shape of the object 14 can be measured.

The point A located on the edge of the cube is a position at which luminance and color tone change greatly compared to those at a position located next to the point A on the image (for example, the background behind the object 14). Even when the irradiation with the pattern light is not performed on boundary portions of the luminance and the color tone, the position (corresponding point) corresponding to the point A is easily recognized in each of the image G1 captured by the first camera 25 and the image G2 captured by the second camera 26, and the depth information based on triangulation can be acquired.

When a certain point positioned on a surface of the cube, such as a point B, is to be measured, there may be almost no difference in the luminance and the color tone compared to the surroundings. Thus, it may be difficult to identify which the coordinates in the image G2 captured by the second camera 26 corresponds to the point corresponding to the coordinates (x1B, y1B) of the point B in the image G1 captured by the first camera 25, and the depth may not be measured based on triangulation. In particular, it is difficult to recognize the corresponding point using the three-dimensional measurer 15, for an object having poor characteristics in terms of shading, shape, color, and the like, such as a monochromatic wall surface or a human face.

As illustrated in FIG. 2 and FIGS. 3A to 3D, the pattern light projector 13 according to the embodiment projects pattern light onto an object to add a characteristic as a luminance to a portion having no characteristic. FIGS. 2 and 3A to 3D illustrate a case where the pattern light projector 13 projects stripe pattern light PS onto a certain cube serving as an object 14. The stripe pattern light PS includes a plurality of stripes at different intervals. The stripe pattern light PS forms a binary stripe pattern on a surface of the cube. Thus, information on contrast in the x-axis direction is increased. Consequently, at the point B on the surface of the cube, a difference in luminance is generated with respect to peripheral pixels (contrast is increased), and the coordinates (x1B, y1B) in the image G1 captured by the first camera 25 and the coordinates (x2B, y2B) in the image G2 captured by the second camera 26 become recognizable. That is, the point A and the point B can be recognized as corresponding points so that their depth information can be acquired. Projecting pattern light in this way enables depth information to be acquired even for a portion having no characteristic.

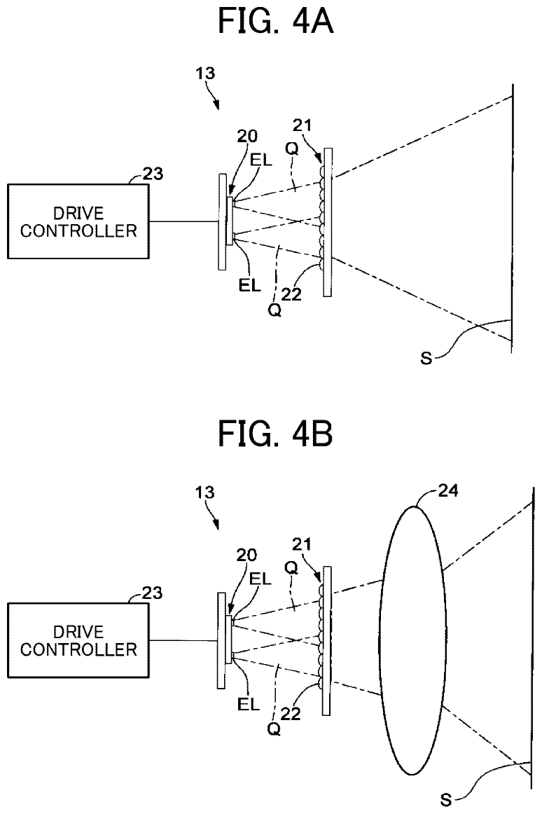

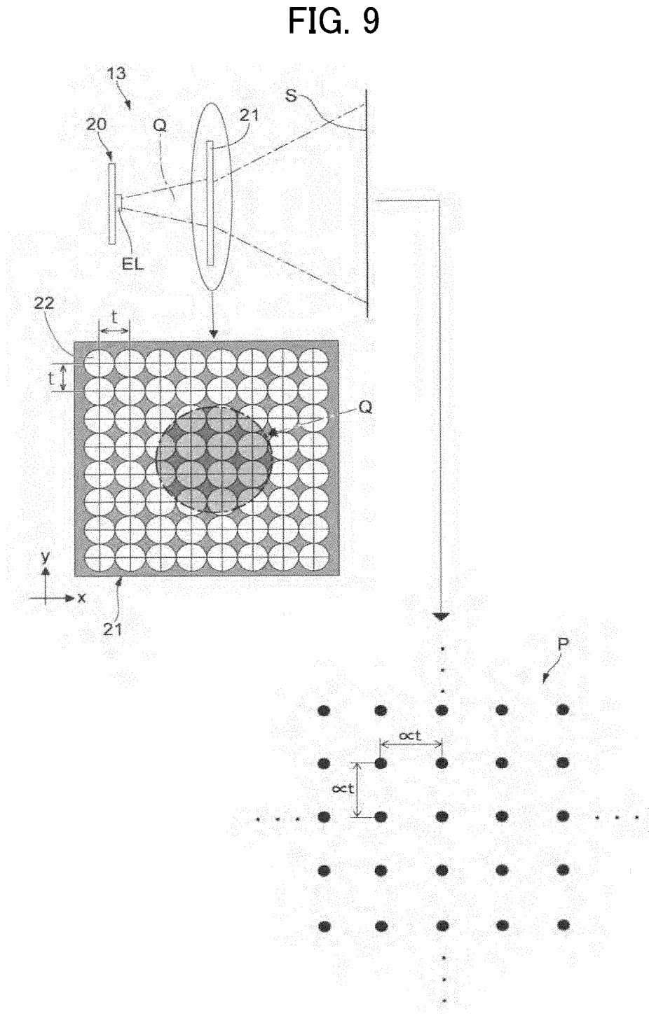

FIGS. 4A and 4B illustrate the pattern light projector 13 included in the measurement device 11. The array light source 20 included in the pattern light projector 13 is a surface emitting laser, and includes a plurality of surface emitting laser elements (hereinafter referred to as light emitting elements) EL arranged in a predetermined positional relationship on a light emitting surface. In this embodiment, vertical cavity surface emitting lasers (VCSELs) are used as the light emitting elements EL. The drive controller 23 controls the output power, radiation angle, driving conditions (pulse width, repetition frequency, emission timing, and the like) of each of the light emitting elements EL of the array light source 20. The microlens array 21 includes the plurality of microlenses 22 arranged regularly (see FIGS. 9 to 11 for specific arrangements).

A laser beam Q oscillated from each light emitting element EL of the array light source 20 is incident on the microlens array 21 with a beam diameter larger than the pitch between the lenses of the microlens array 21, expanded by the microlens array 21, and emitted on an object. FIGS. 4A and 4B each illustrate an irradiation plane S as a virtual plane at the position of the object. FIG. 4A illustrates a configuration in which an optical system that provides irradiation with a laser beam Q emitted from the array light source 20 includes the microlens array 21. FIG. 4B illustrates a configuration including another optical element 24 in rear of the microlens array 21 to provide irradiation at a wider angle. As the optical element 24, a lens having a negative power, a diffusion plate, or the like, can be used. The number of optical elements 24 may be single or plural.

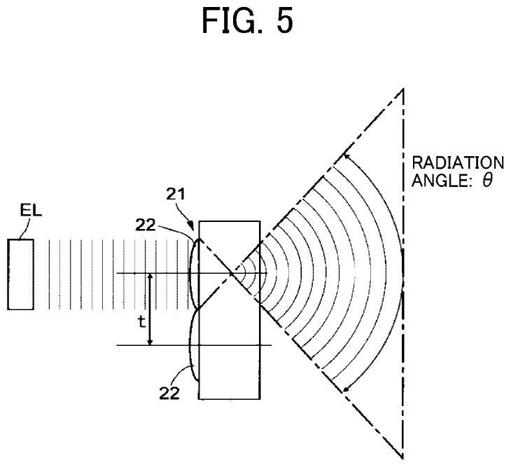

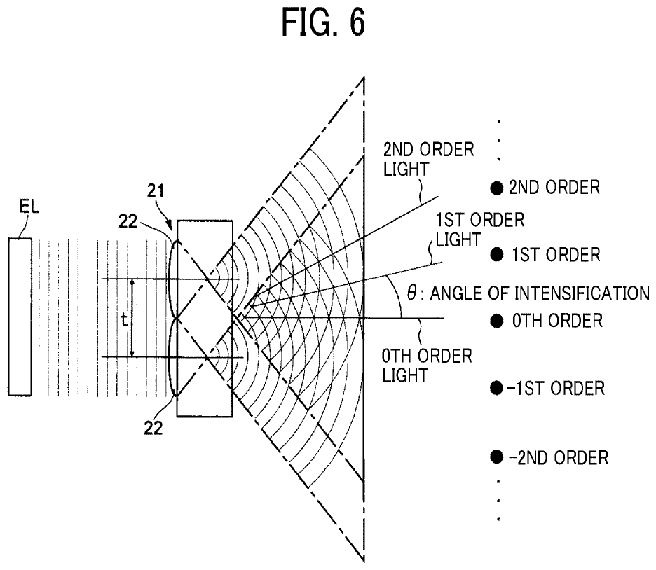

The pattern light projector 13 is configured such that laser beams emitted from the microlenses 22 of the microlens array 21 interfere with each other to project periodic pattern light depending on the pitch and array of the microlenses 22. Referring to FIGS. 5 and 6, formation of pattern light by the pattern light projector 13 is described. In FIGS. 5 and 6, to simplify the description, it is assumed that the microlens array 21 includes a plurality of microlenses 22 arranged one-dimensionally (in series) at a constant lens pitch t.

FIG. 5 illustrates a configuration in which plane waves of a laser beam emitted by one light emitting element EL of the array light source 20 are incident on one microlens 22 included in the microlens array 21. In this case, the incident laser beam is condensed and diverged at a radiation angle Θ determined in accordance with the curvature, refractive index, or the like, of the microlens 22, and is emitted from the microlens array 21. The laser beam emitted from the one light emitting element EL is transmitted through the one microlens 22. Laser beams emitted from respective microlenses 22 do not interfere with one another.

As illustrated in FIG. 6, when plane waves of a laser beam emitted by one light emitting element EL of the array light source 20 are incident on a plurality of microlenses 22 included in the microlens array 21, light with a radiation angle Θ is diverged and emitted from each of the microlenses 22. Since beams of light emitted from the respective microlenses 22 are beams of light generated from the same plane wave, the beams of light emitted from the microlenses 22 have the same wavefront even after being emitted from the microlenses 22. Consequently, the beams of light emitted from the respective microlenses 22 interfere with one another, and are intensified at an angle θ depending on the wavelength λ and the pitch t between the microlenses 22 as expressed by the following Expressions (1) and (1′). In Expression (1), m is an integer.

t sin θ=±mλ (1)

θ=sin⁻¹(λ/t) (1′)

That is, when light is incident on at least two microlenses 22, the number m<Θ/θ (m is an integer) of beams of pattern light are generated at the period of the angle θ. When microlenses 22 of the microlens array 21 are one-dimensionally arranged, beams of pattern light are also one-dimensionally arranged.

Even if the light incident on the microlens array 21 is a divergent laser beam such as a Gaussian beam, as far as the beam diameter is sufficiently large, the light is recognized as plane waves in the microlens array 21, interference occurs, and pattern light is formed.

In the pattern light projector 13 according to the embodiment, as illustrated in FIG. 6, the laser beam emitted from one light emitting element EL included in the array light source 20 is made incident on the plurality of microlenses 22 to project pattern light having predetermined periodicity.

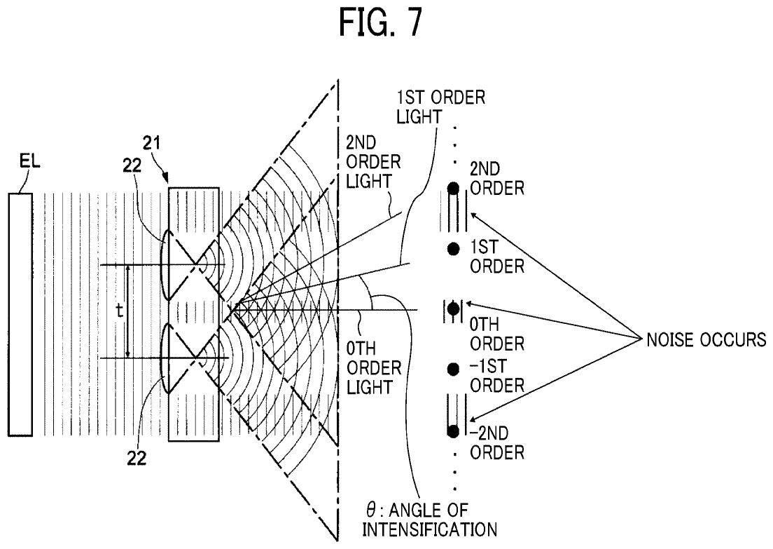

When a laser beam emitted from one light emitting element EL is made incident on the plurality of microlenses 22, it is required to prevent light from passing through a portion between adjacent microlenses 22 (see FIG. 7). Since light transmitted without passing through the microlens 22 travels straight without causing interference as described above, 0th order interference light is intensified or such light turns into a background noise of pattern light to be projected, reducing the contrast of the pattern light.

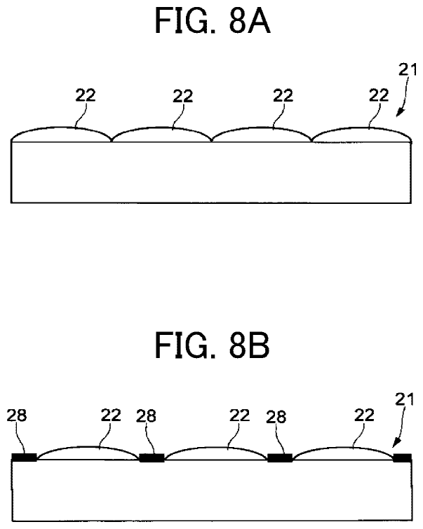

To address this, as illustrated in FIG. 8A, a microlens array 21 having a configuration in which a plurality of microlenses 22 are arranged adjacent to each other so as not to have a gap therebetween is used. Alternatively, as illustrated in FIG. 8B, a microlens array 21 having a structure in which a gap between a plurality of microlenses 22 is closed with a light shielding member 28 that does not transmit light may be used.

FIG. 6 described above illustrates a simplified model in which microlenses 22 are arranged one-dimensionally. FIGS. 9 to 11 each illustrate formation of pattern light by one light emitting element EL and two-dimensionally arranged microlenses 22. In the microlens array 21 of any one of the configurations illustrated in FIGS. 9 to 11, the microlenses 22 each have a circular outer shape, and the gap between the microlenses 22 is closed with a light shielding member (see FIG. 8B).

In a configuration example of a microlens array 21 illustrated in FIG. 9, a plurality of microlenses 22 are arranged in a square lattice form at a constant pitch t in both the x-axis direction and the y-axis direction. Then, a laser beam Q emitted from a light emitting element EL is set to be incident on the microlens array 21 in an incident range of a beam diameter including at least two microlenses 22 in each of the x-axis direction and the y-axis direction. Thus, beams of light emitted from the microlenses 22 on which the laser beam Q is incident interfere with each other in both the x-axis direction and the y-axis direction to generate two-dimensional pattern light P. The angle of the period of the pattern light P is determined by the above Expression (1′). The arrangement of the pattern light P is determined based on the lens arrangement of the microlens array 21, that is, in FIG. 9, pattern light P in a square lattice form is formed to correspond to the microlenses 22 arranged in a square lattice form.

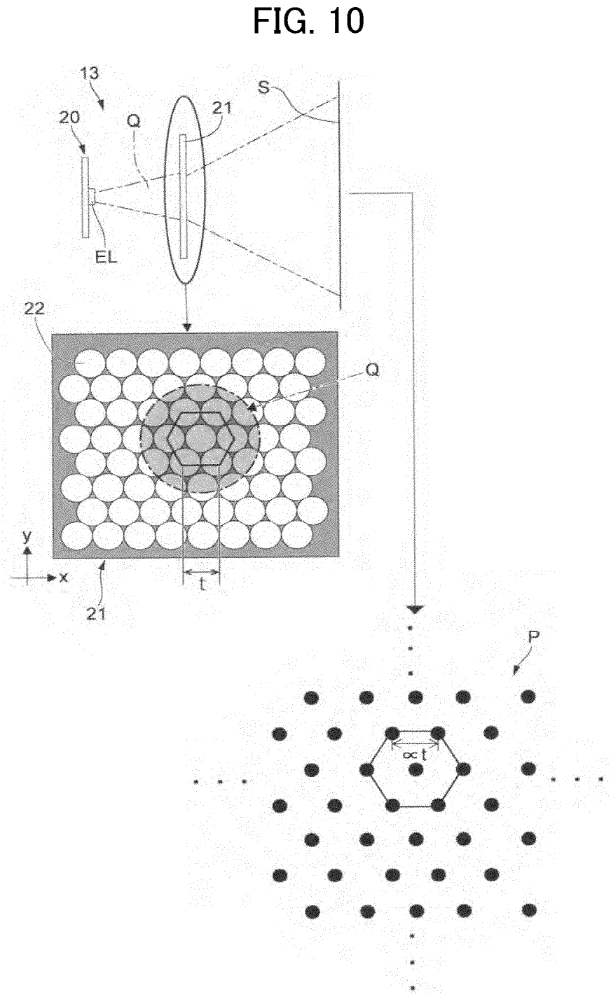

In a configuration example of a microlens array 21 illustrated in FIG. 10, the centers of a plurality of microlenses 22 are arranged at the vertices of continuous equilateral triangles defined by sides of the same lens pitch t, that is, in a hexagonal filling arrangement (hexagonal arrangement). In this case, when a laser beam Q from a light emitting element EL is made incident in an incident range including at least two microlenses 22 in each of the x-axis direction and the y-axis direction, hexagonal-lattice-form (regular-triangle-lattice-form) pattern light P is formed to correspond to the arrangement of the microlenses 22.

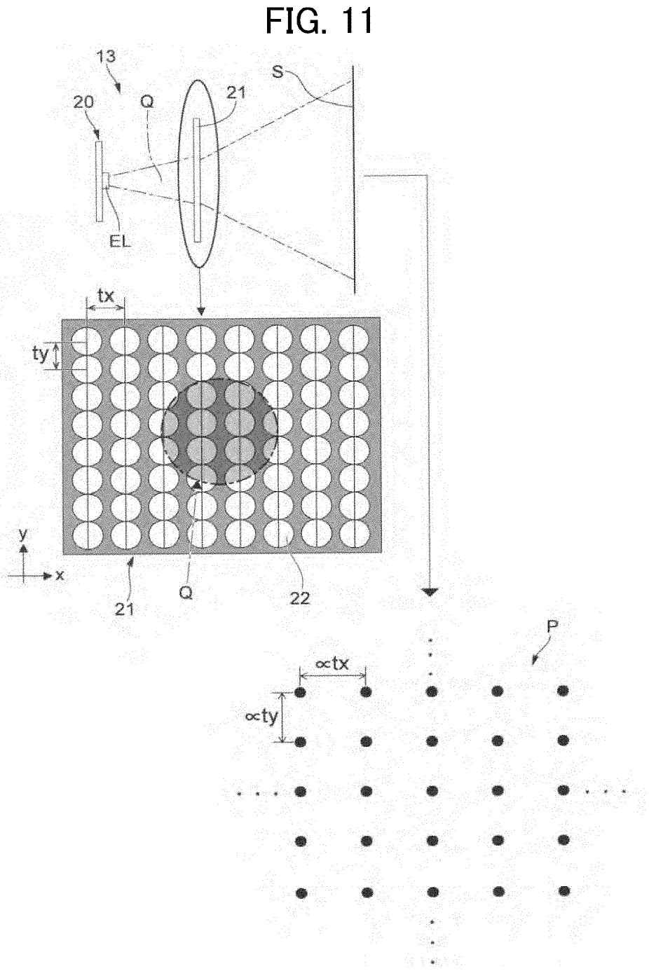

In a configuration example of a microlens array 21 illustrated in FIG. 11, a plurality of microlenses 22 are arranged at a constant pitch tx in the x-axis direction, and are arranged at a constant pitch ty in the y-axis direction. The values of the pitch tx and the pitch ty differ from each other (tx>ty). That is, the plurality of microlenses 22 are arranged in a rectangular lattice form (rectangular arrangement) which is not a square lattice form. In this case, when a laser beam Q from a light emitting element EL is made incident in an incident range including at least two microlenses 22 in each of the x-axis direction and the y-axis direction, rectangular-lattice-form pattern light P corresponding to the arrangement of the microlenses 22 is formed.

Referring to FIGS. 6, and 9 to 11, the formation of the pattern light by one light emitting element EL has been described; however, in an actual pattern light projector 13, the array light source 20 includes a plurality of light emitting elements EL on a light emitting surface parallel to the microlens array 21. The formation of pattern light by the pattern light projector 13 including a plurality of light emitting elements EL will be described below.

When the microlens array 21 is irradiated with a laser beam from each of a plurality of light emitting elements included in the array light source 20 to include a plurality of microlenses 22 in an incident range, the laser beams emitted from the respective light emitting elements are made to be incoherent laser beams (with undulations not interfering with each other) whose phases are not aligned with each other, thereby generating individual pattern light per light emitting element without interference between laser beams emitted from the microlens array 21.

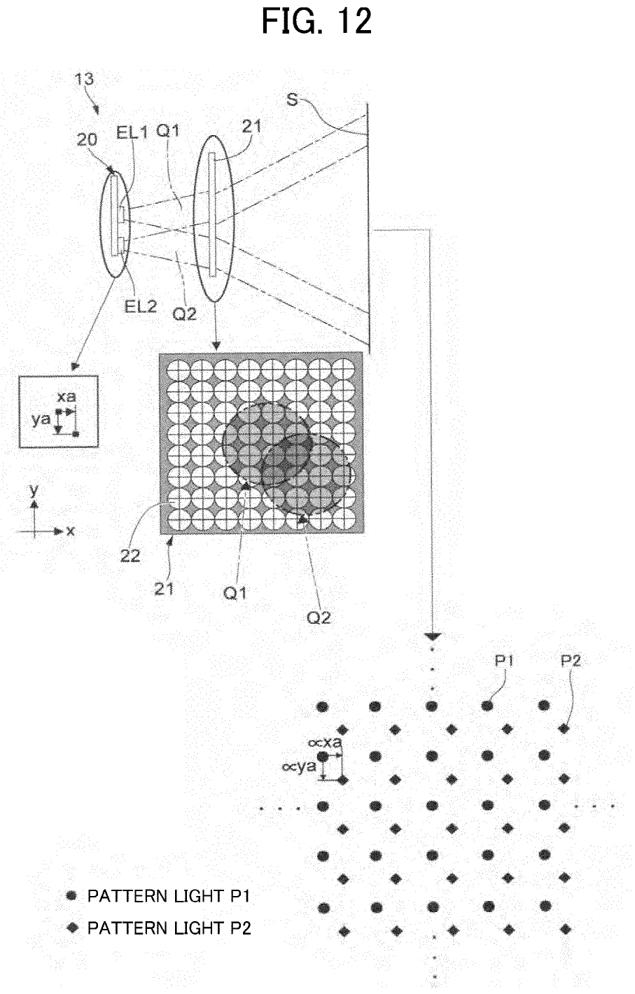

For example, as illustrated in FIG. 12, it is assumed that there are two light emitting elements EL1 and EL2 in the array light source 20, and that the light emitting element EL2 is shifted from the light emitting element EL1 by xa in the x-axis direction and by ya in the y-axis direction. At this time, when a laser beam Q1 emitted from the light emitting element EL1 and a laser beam Q2 emitted from the light emitting element EL2 are made to be incident on a plurality of microlenses 22 of the microlens array 21 in such a manner that the laser beam Q1 and the laser beam Q2 partially overlap each other as illustrated in FIG. 12, light which is intensified at the same angle is generated. However, since the laser beam Q1 and the laser beam Q2 are in an incoherent relationship, the laser beam Q1 and the laser beam Q2 do not interfere with each other. Thus, the pattern light P2 based on the laser beam Q2 emitted from the light emitting element EL2 is independently formed at a position shifted from the pattern light P1 based on the laser beam Q1 emitted from the light emitting element EL1 by an amount depending on the amount of shift (xa, ya) between the light emitting element EL1 and the light emitting element EL2. That is, when incoherent light is incident on the microlens array 21 from the array light source 20, periodic pattern light is generated in which the light source arrangement (relative positional relationship of the light emitting elements) in the array light source 20 is transferred.

The pattern to be projected by the pattern light projector 13 is required to have no similar pattern, that is, required to have a pattern having randomness within a parallax search range in which the three-dimensional measurer 15 extracts corresponding points in an image of the first camera 25 and an image of the second camera 26. If the same pattern appears as a result of searching within the parallax search range, it is difficult to determine which is the corresponding point on the image, and the corresponding point may be erroneously verified. When the object moves back and forth with respect to the measurement distance expected to be measured by the three-dimensional measurer 15, the pattern light on the object (irradiation plane) is enlarged or reduced. Then, even if the pattern projected by the pattern light projector 13 has randomness, the pattern to be detected by the three-dimensional measurer 15 may lose randomness due to enlargement or reduction of the pattern light. Thus, it is desirable to project a pattern having both periodicity and randomness so that randomness can be maintained even when the pattern is enlarged or reduced.

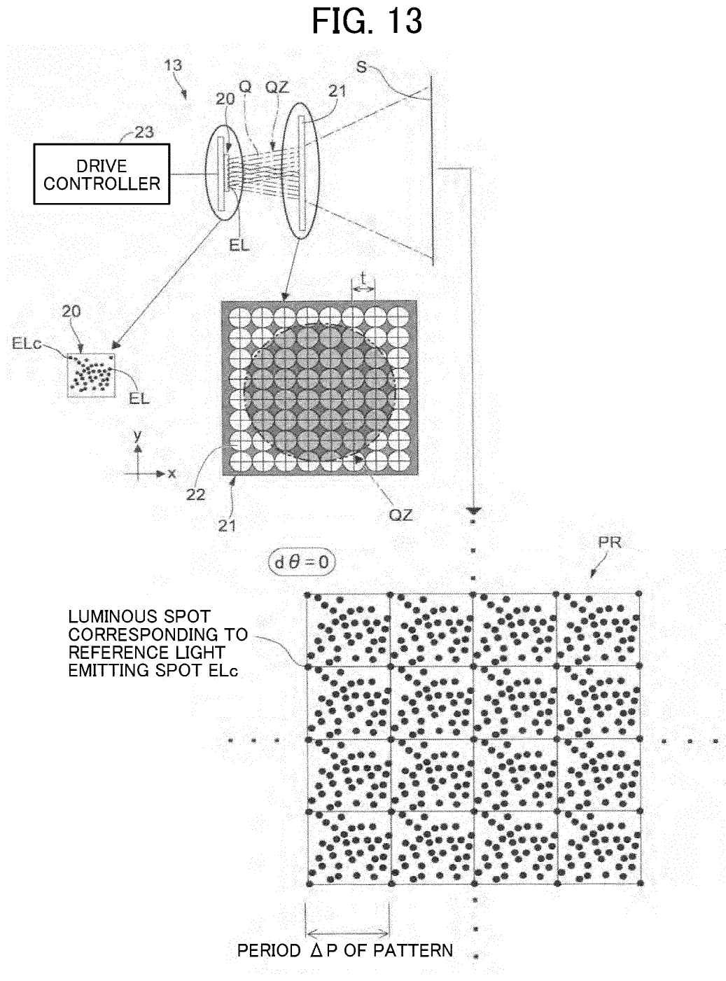

FIG. 13 illustrates a pattern light projector 13 having a configuration that generates pattern light having both randomness and periodicity. The pattern light projector 13 includes an array light source 20 in which a plurality of light emitting elements EL are arranged to be unevenly spaced from each other in each of the x-axis direction and the y-axis direction (to have an uneven positional relationship), and a microlens array 21 in which a plurality of microlenses 22 are arranged at a constant lens pitch t. A laser beam Q emitted from each light emitting element EL is incident on at least two microlenses 22 in both the x-axis direction and the y-axis direction. A group of laser beams Q emitted from the plurality of light emitting elements EL is represented in FIG. 13 as a composite laser beam QZ.

As described above referring to FIG. 12, when the array light source 20 including the light emitting elements each emit incoherent light is used as a light source, a plurality of beams of independent (interference free) pattern light can be formed in accordance with the positions of the light emitting elements. Accordingly, in the pattern light projector 13 illustrated in FIG. 13, pattern light PR to which a random arrangement of the plurality of light emitting elements EL in the array light source 20 is transferred is formed. Moreover, in the pattern light projector 13 illustrated in FIG. 13, a positional relationship between the array light source 20 and the microlens array 21 is determined such that laser beams Q emitted from all the light emitting elements EL in the array light source 20 are incident on two or more microlenses 22 in each of the x-axis direction and the y-axis direction when the laser beams Q are incident on the microlens array 21. Accordingly, the laser beams emitted from the light emitting elements EL in the array light source 20 pass through the microlens array 21 to generate interference light (see FIG. 6). Consequently, the pattern light PR having both the randomness and the periodicity as illustrated in FIG. 13 can be projected.

Since the pattern light having both the randomness and the periodicity is projected onto an object, the three-dimensional measurer 15 can perform measurement even in the case of an object whose characteristic is difficult to be detected through projection with uniform light. As described above, the randomness in the pattern light to be projected represents that a similar pattern does not appear within the range of parallax search to be performed for recognizing the corresponding points by the first camera 25 and the second camera 26 of the three-dimensional measurer 15.

The length of the period of the pattern light projected by the pattern light projector 13 depends on the parallax search range of the first camera 25 and the second camera 26 in the three-dimensional measurer 15 and the number of pixels when the corresponding point is extracted. That is, when the irradiation region with pattern light is image captured by the cameras 25 and 26, the length until a predetermined luminous spot of a pattern appears repeatedly in the arrangement direction of the pixels of the image sensor serves as the length of the period of the pattern. The pitch t between the microlenses 22 of the microlens array 21 is reduced, and the angle θ of intensifying the interference light generated by making the laser beam incident on the plurality of microlenses 22 is increased, thereby lengthening the period. However, increasing the angle θ corresponds to enlarging the region in which the random pattern is projected. To attain this, the area of the array light source 20 and the number of light emitting spots are required to be increased. Consequently, the cost for manufacturing the array light source 20 and the size of a circuit (drive controller 23) for driving the array light source 20 may be increased.

FIG. 13 illustrates a case where the arrangement direction of the microlenses 22 (the arrangement axis along which the microlenses 22 are arranged) of the microlens array 21 is the same as the pixel arrangement direction of the image sensors of the cameras 25 and 26, that is, the case where dθ=0. At this time, the period of the pattern in the x-axis direction in the pattern light PR is ΔP which directly reflects the arrangement of the light emitting elements EL of the array light source 20. For example, in a case where a specific light emitting element EL of the array light source 20 is set as a reference light emitting spot ELc, when the pattern light PR is image captured by the cameras 25 and 26, a luminous spot corresponding to the reference light emitting spot ELc appears per period ΔP.

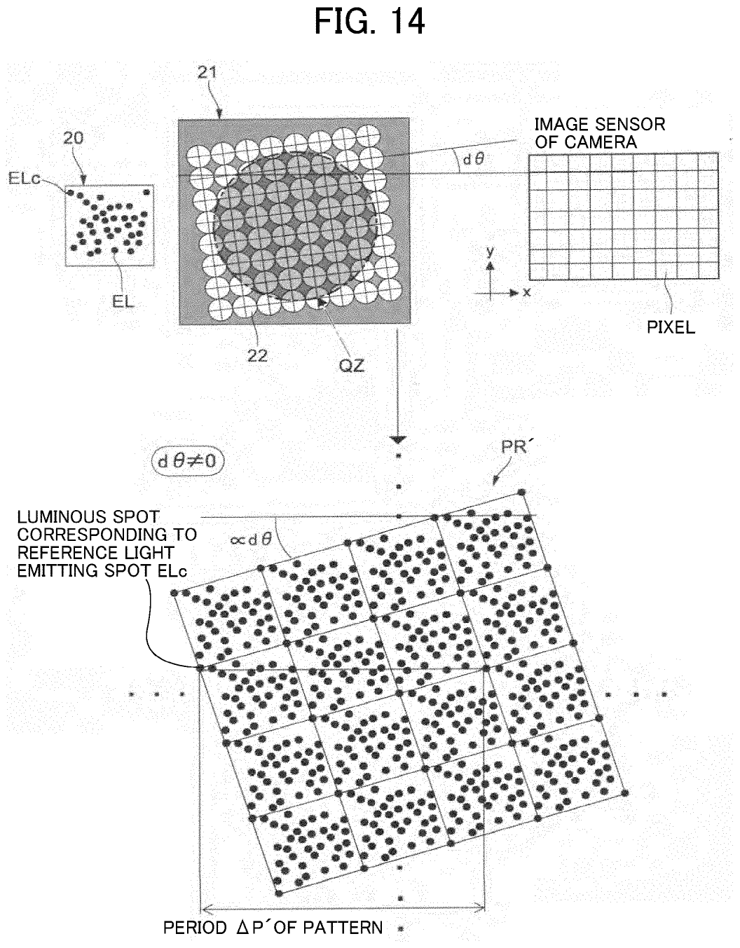

FIG. 14 illustrates a method of forming pattern light having randomness in a long period without increasing the area of the array light source 20 or increasing the number of light emitting spots. The configuration in FIG. 13 and the configuration in FIG. 14 are under the same conditions, the conditions including the area of the array light source 20, the number of the light emitting elements EL, and the lens pitch of the microlens array 21. In the configuration illustrated in FIG. 14, the arrangement direction of the microlenses 22 (the arrangement axis along which the microlenses 22 are arranged) of the microlens array 21 is rotated by an angle dθ with respect to the pixel arrangement direction of the image sensors in the first camera 25 and the second camera 26. Moreover, the array light source 20 is rotated by an angle dθ with respect to the configuration illustrated in FIG. 13. Then, pattern light PR′ to be projected is also rotated depending on the angle dθ, so that a period ΔP′ of the pattern light in the x-axis direction (the length until the luminous spot corresponding to the reference light emitting spot ELc appears next) becomes longer (ΔP′>ΔP). In other words, with the pattern light PR′, the period in which the randomness is repeated is longer than that with the pattern light PR (FIG. 13). Thus, even when the angle θ of intensification due to interference is small, it is possible to project random pattern light in a long period without increasing the area of the array light source 20.

In the example illustrated in FIG. 14, both the array light source 20 and the microlens array 21 are inclined at the angle dθ with respect to the pixel arrangement direction of the image sensor. Alternatively, the arrangement direction of the microlenses 22 of the microlens array 21 may be inclined at the angle dθ without rotating the array light source 20. Even in this case, the advantageous effect of lengthening the period of the pattern in the pixel arrangement direction of the image sensor is obtained.

A plurality of light emitting spots (light emitting elements EL) are randomly arranged and emit light having different light intensities to improve the randomness of the pattern light that is projected by the pattern light projector 13. When the light intensities of the pattern light have binary values, a pattern to be expressed may be limited, and an erroneous point may be detected in the corresponding point search by the three-dimensional measurer 15. In such a case, the pattern light is projected with light intensities of trinary or more values to improve the recognition rate of the corresponding point.

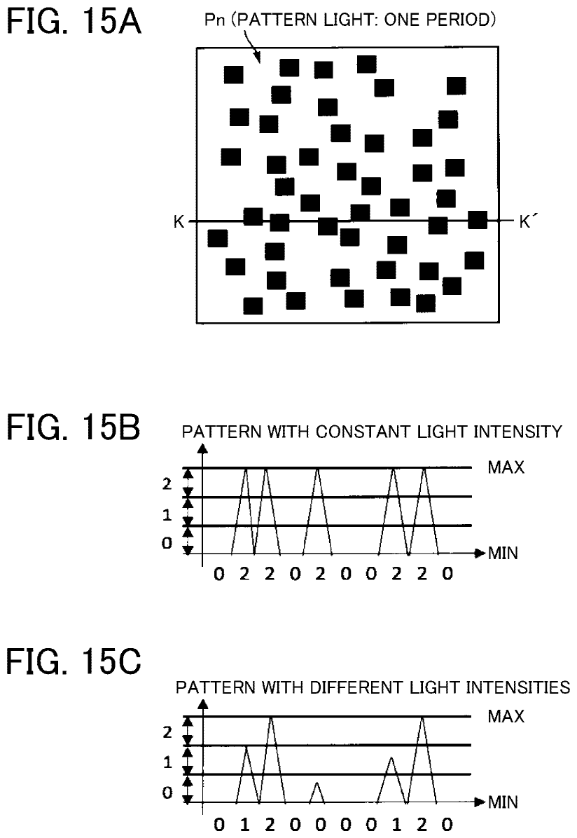

FIGS. 15A to 15C illustrate a comparison between a case where light emitting elements EL emit light with a constant intensity and a case where light emitting elements EL emit light with different intensities in the array light source 20. FIG. 15A illustrates one period Pn extracted from pattern light. FIGS. 15B and 15C illustrate intensity distributions of light along a predetermined section K-K′ in the period Pn. Quantization is performed with reference to the maximum intensity and the minimum intensity in the pattern, and the quantized values are equally divided into three groups of luminance. Then, corresponding one of the luminance groups is determined for each pixel on the image sensors of the first camera 25 and the second camera 26 in the three-dimensional measurer 15.

FIG. 15B illustrates a case where the light emitting elements EL included in the array light source 20 are controlled to have the same emission amount. In this case, the intensities of luminous spots in the pattern to be generated are also the same, and the intensities of the pattern light are expressed by binary values of “0” and “2”.

FIG. 15C illustrates a case where the light emitting elements EL included in the array light source 20 are controlled to have different emission amounts. In this case, there appears a difference in the light intensity of pattern light to be projected, and an intensity distribution of trinary or more values including “0”, “2”, and also an intermediate value between them is produced. Consequently, the randomness of pattern light can be improved and the recognition rate of the corresponding points by the two cameras 25 and 26 can be improved.

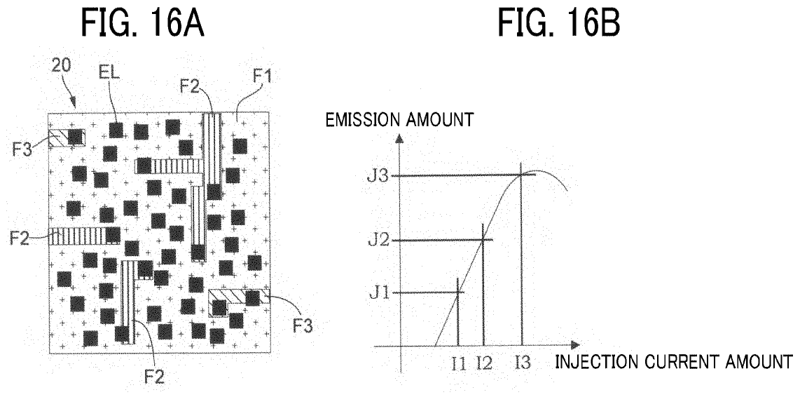

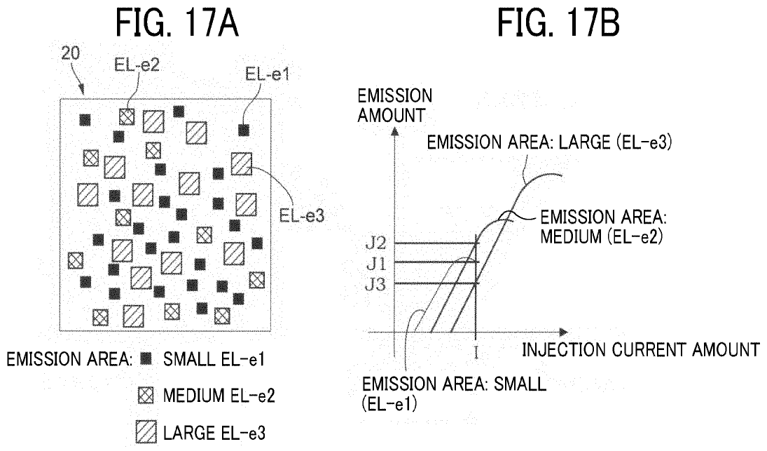

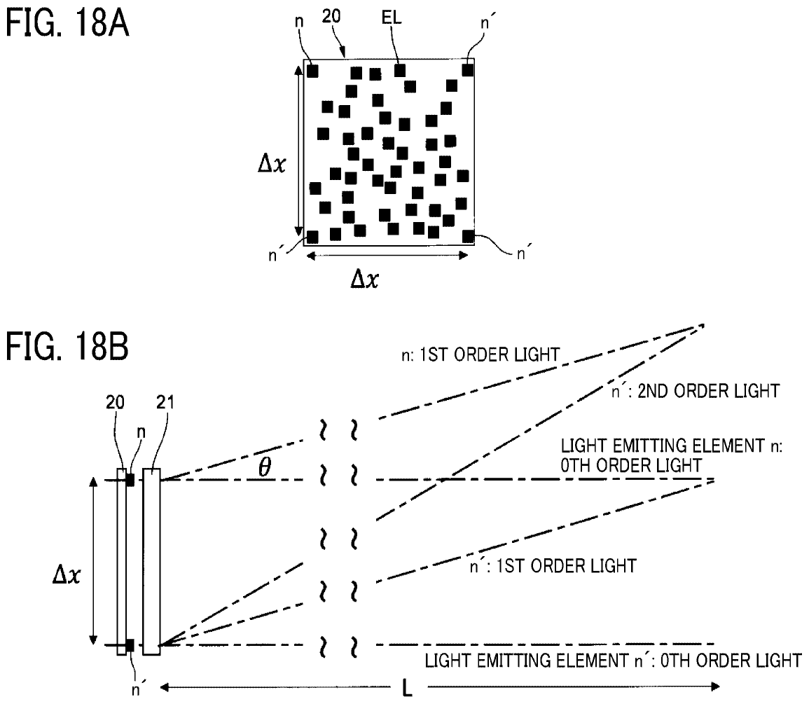

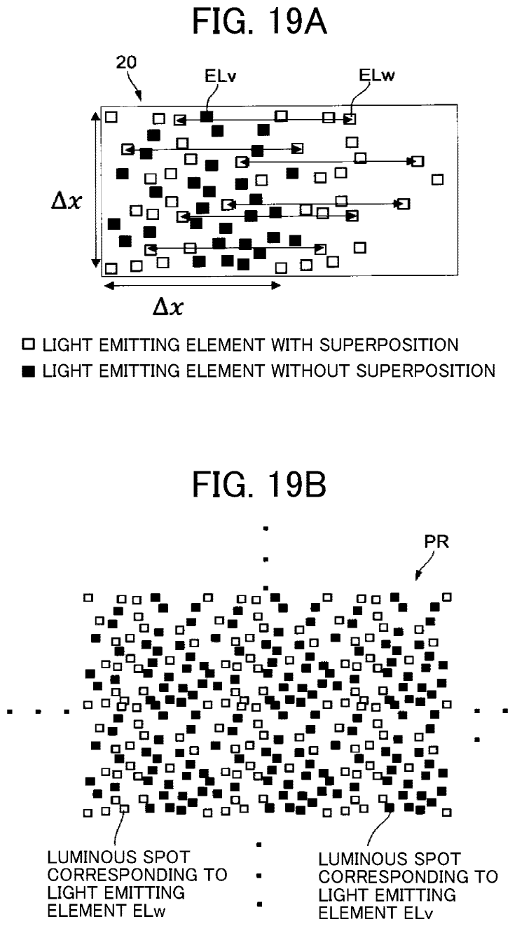

Referring to FIGS. 16A to 19B, a method of making a difference among the intensities of the pattern light in the array light source 20 will be described. FIGS. 16A, 16B, 17A, and 17B illustrate a configuration in which individual light emitting elements have different emission amounts and different emission areas, and FIGS. 18A, 18B, 19A, and 19B illustrate a configuration in which beams of light emitted from a plurality of light emitting elements are superposed to have different intensities.

FIGS. 16A and 16B illustrate an example in which electrodes that supply electric current to light emitting elements EL in an array light source 20 have at least two electrode patterns. As illustrated in FIG. 16A, three independent electrode patterns F1, F2, and F3 are formed in the array light source 20. FIG. 16B is a graph illustrating the relationship of an emission amount J with respect to an injection current amount I in light emitting elements EL having the same emission area. The emission amount J linearly increases until the injection current amount I reaches a saturation point. The injection current amounts to individual light emitting elements EL are made different such that the electrode pattern F1 has an injection current amount IL the electrode pattern F2 has an injection current amount I2, and the electrode pattern F3 has an injection current amount 13. Thus, the light emitting elements EL classified based on the electrode patterns can emit light with the different emission amounts J1, J2, and J3. Consequently, the pattern light expressed by the four values corresponding to four levels of emission amounts (0, J1, J2, J3) can be projected.

FIGS. 17A and 17B illustrate an example in which light emitting elements EL of an array light source 20 have at least two kinds of different emission areas. As illustrated in FIG. 17A, the plurality of light emitting elements EL provided on the array light source 20 are divided into three kinds of different emission areas including a small area (EL-e1), a medium area (EL-e2), and a large area (EL-e3).

As illustrated in FIG. 17B, as the emission area of a light emitting element EL increases, the injection current amount required to oscillate a laser beam tends to increase. Thus, when the injection current amount I to each of the light emitting elements EL is constant, the emission amount J1 of the light emitting element EL-e1 having a small area, the emission amount J2 of the light emitting element EL-e2 having a medium area, and the emission amount J3 of the light emitting element EL-e3 having a large area are provided in the order of J2>J1>J3. Consequently, the pattern light expressed by the four values corresponding to the four levels of emission amounts (0, J1, J2, J3) can be projected. When a VCSEL is used as a light emitting element, for example, an emission area can be selected from a range of 20 μm² to 500 μm².

In the examples illustrated in FIGS. 16A, 16B, 17A, and 17B, the amounts of injection current to the light emitting elements EL and the emission areas of the light emitting elements EL are different at three levels; however, these values may be different at two levels or four or more levels.

FIGS. 18A and 18B illustrate an example in which a corresponding light emitting element n′ is disposed at a position shifted by a predetermined amount (Δx) from a light emitting element n in at least one of the x-axis direction and the y-axis direction in the array light source 20 to increase the luminance of a specific spot arranged periodically in pattern light. The light emitting element n and the light emitting element n′ emit incoherent laser beams. As described above referring to FIG. 12, when the light emitting elements of the array light source 20 emit beams of incoherent light, the beams of incoherent light do not interfere with each other, and beams of pattern light are shifted depending on the shift amounts of the light emitting elements.

As illustrated in FIG. 18B, m-th order interference light of the light emitting element n and m−1-th order interference light of the light emitting element n′ are superposed on each other to increase (double) the luminance of the pattern light in the portion where the intensities are superposed. In contrast, light emitted from light emitting elements EL located at positions other than the light emitting elements n and n′ do not cause the above-described superposition of interference light. That is, light with a first intensity obtained by superposition of light emitted from a plurality of light emitting elements n and n′ and light with a second intensity emitted from one light emitting element EL are generated.

Specifically, when L denotes a light projection distance, t denotes a lens pitch of the microlens array 21, and X denotes a wavelength of light oscillated by a light emitting element, to superpose interference light of light emitting elements, a light emitting element may be arranged at a position shifted by Δx which satisfies the following Expression (2) in a direction parallel to the lens arrangement axis of the microlens array 21 or in a direction perpendicular to the lens arrangement axis (one or both of the x-axis direction and the y-axis direction).

$$Δ x = L tan θ = L tan ( {sin}^{- 1} \frac{λ}{t} ) = L \frac{( λ / t )}{\sqrt{1 - {( λ / t )}^{2}}} \qquad ( 2 )$$

FIG. 18A illustrates a case where the light emitting element n and the light emitting element n′ whose beams of interference light are superposed (that is, arranged at an interval Δx) are arranged at the four corners of the array light source 20. FIG. 19A illustrates a case where a plurality of light emitting elements are arranged at an interval Δx at which superposition of interference light occurs at any position not limited to the four corners in the array light source 20. In FIG. 19A, white dots indicate light emitting elements ELw in the arrangement where superposition of interference light occurs, and black dots indicate light emitting elements ELv in the arrangement where superposition of interference light does not occur.

FIG. 19B illustrates pattern light PR projected with periodicity through the microlens array 21 using the array light source 20 illustrated in FIG. 19A. In FIG. 19B, white dots indicate luminous spots corresponding to the light emitting elements ELw in the arrangement where superposition of interference light occurs, and black dots indicate luminous spots corresponding to the light emitting elements ELv in the arrangement where superposition of interference light does not occur. As illustrated in FIG. 19B, in addition to the periodicity of the pattern corresponding to the lens arrangement of the microlens array 21 and the randomness of the pattern corresponding to the arrangement of the light emitting elements of the array light source 20, the pattern also has different light intensities, so that the recognition rate of the corresponding point in the three-dimensional measurer 15 can be greatly improved.

As a method for making the intensity of the pattern light emitted from the array light source 20 different, it is possible to use both a method (FIGS. 16A, 16B, 17A, and 17B) in which the emission amounts and the emission areas of the individual light emitting elements are different and a method (FIGS. 18A, 18B, 19A, and 19B) in which the beams of light emitted from the plurality of light emitting elements are superposed on each other to increase the intensity of the light.

As described above, in the pattern light projector 13 to which the present disclosure is applied, an object can be irradiated with complex pattern light having periodicity and randomness using a simple configuration in which laser beams emitted from the individual light emitting elements in the array light source 20 are made incident on the plurality of microlenses 22 of the microlens array 21. Thus, the measurement (detection) accuracy of the measurement device 11 using the pattern light projector 13 and the object recognition accuracy in the object recognition apparatus 10 incorporating the measurement device 11 are improved.

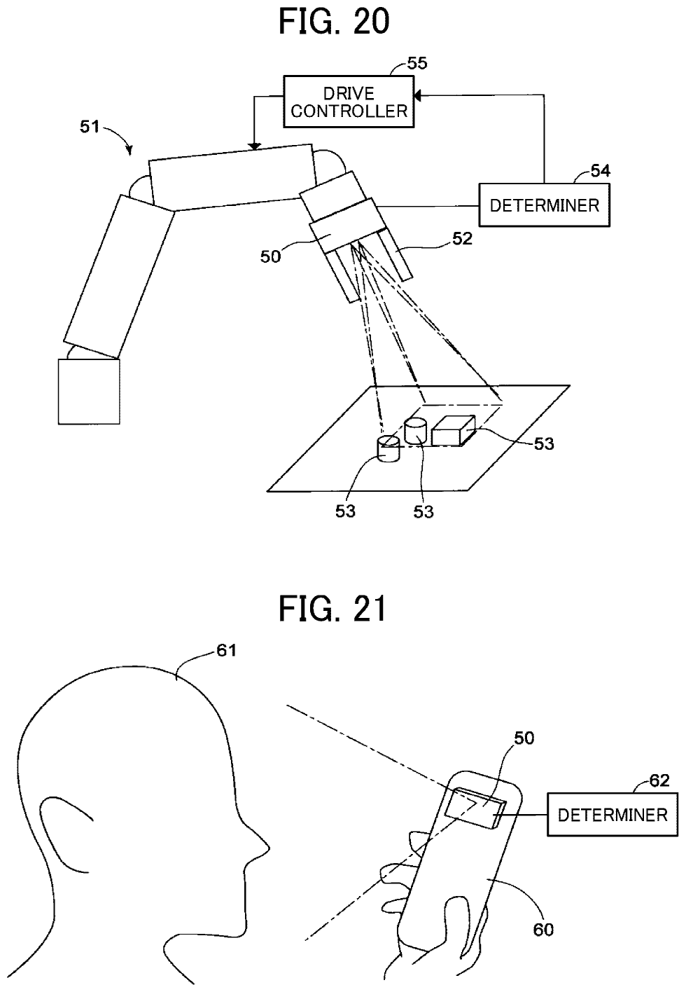

Application examples in which the pattern light projector 13 described above is used in various electronic apparatuses will now be described referring to FIGS. 20 to 24. A detection device 50 in each of these application examples corresponds to a portion of the measurement device 11 in the object recognition apparatus 10 illustrated in FIG. 1. In the detection device 50, the three-dimensional measurer 15, the arithmetic processor 16, and the measurement controller 17 illustrated in FIG. 1 serve as a detector that detects light emitted from the pattern light projector 13 and reflected by an object. In FIGS. 20 to 24, functional blocks such as a determiner included in the detection device 50 are illustrated outside the detection device 50 for convenience of drawing.

FIG. 20 illustrates an application example in which a detection device 50 is used for operational control on a movable apparatus. An articulated arm 51 is a movable apparatus. The articulated arm 51 includes a plurality of arms coupled by a bendable joint, and a hand portion 52 provided at a distal end thereof. The articulated arm 51 is used, for example, in an assembly line of a factory, and grips an object 53 by the hand portion 52 during inspection, conveyance, and assembly of the object 53.

The detection device 50 is mounted at a position closest to the hand portion 52 of the articulated arm 51. The detection device 50 is provided so that a projection direction of light from the pattern light projector 13 coincides with a direction in which the hand portion 52 faces, and detects the object 53 and the peripheral region thereof as an object to be detected. The detection device 50 receives reflected light from an irradiation region including the object 53 using the three-dimensional measurer 15, performs image capturing, and generates image data. Based on obtained image information, a determiner 54 determines various kinds of information related to the object 53. Specifically, information detected using the detection device 50 includes a distance to the object 53, a shape of the object 53, a position of the object 53, and if a plurality of objects 53 are present, a positional relationship among the objects 53. Then, based on the determination result in the determiner 54, a drive controller 55 controls the operation of the articulated arm 51 and the hand portion 52 to grip or move the object 53.

In the application example of FIG. 20, since the detection device 50 (pattern light projector 13) capable of projecting pattern light (having both periodicity and randomness) with which a plurality of cameras (first camera 25 and second camera 26) in the three-dimensional measurer 15 can easily recognize corresponding points is used, highly accurate three-dimensional information on the object 53 can be obtained. Moreover, since the detection device 50 is mounted on the articulated arm 51 (in particular, at a position closest to the hand portion 52), the object 53 which is an object to be gripped can be detected from a short distance, and detection accuracy and recognition accuracy can be improved as compared with detection by a far detection device arranged at a position distant from the articulated arm 51.

FIG. 21 illustrates an application example in which a detection device 50 is used for user authentication of an electronic apparatus. A portable information terminal 60 which is an electronic apparatus has an authentication function for a user. The authentication function may be implemented by dedicated hardware or may be implemented by execution of a program by a central processing unit (CPU) that controls the portable information terminal 60. The program may be stored in a memory such as a read only memory (ROM).

To authenticate a user, pattern light is projected from the pattern light projector 13 of the detection device 50 mounted on the portable information terminal 60 to a user 61 using the portable information terminal 60. The three-dimensional measurer 15 of the detection device 50 receives light reflected by the user 61 and the periphery of the user 61 to perform image capturing. A determiner 62 determines the matching degree between image information obtained by image capturing the user 61 using the detection device 50 and user information registered in advance, and determines whether the user is the registered user. That is, the determiner 62 has a comprehensive function including the object register 30, the object memory 31, and the object verifier 32 in the object recognizer 12 of the object recognition apparatus 10 illustrated in FIG. 1. A specific part to be detected as user information by the detection device 50 is the shape (contour or unevenness) of the face, ear, head, or the like, of the user 61.

In the application example of FIG. 21, since the detection device 50 (pattern light projector 13) capable of projecting pattern light with which a plurality of cameras (first camera 25 and second camera 26) in the three-dimensional measurer 15 can easily recognize corresponding points is used, highly accurate three-dimensional information on the user 61 can be obtained. In particular, with use of the pattern light emitted from the pattern light projector 13, three-dimensional information can be reliably obtained even for a portion with less unevenness and low contrast, such as the face of the user 61. Thus an effect of increasing the amount of information for recognizing the user can be obtained, thereby improving recognition accuracy.

FIG. 21 illustrates the example in which the detection device 50 is mounted on the portable information terminal 60; however, the user authentication using the detection device 50 may be used for a stationary personal computer, an office automation (OA) appliance such as a printer, a security system of a building, or the like. Moreover, the function to be used is not limited to the authentication function for an individual, and may be used for scanning a three-dimensional shape such as a face. Even in this case, mounting the detection device 50 (pattern light projector 13) that emits the above-described pattern light can provide scanning with high accuracy.

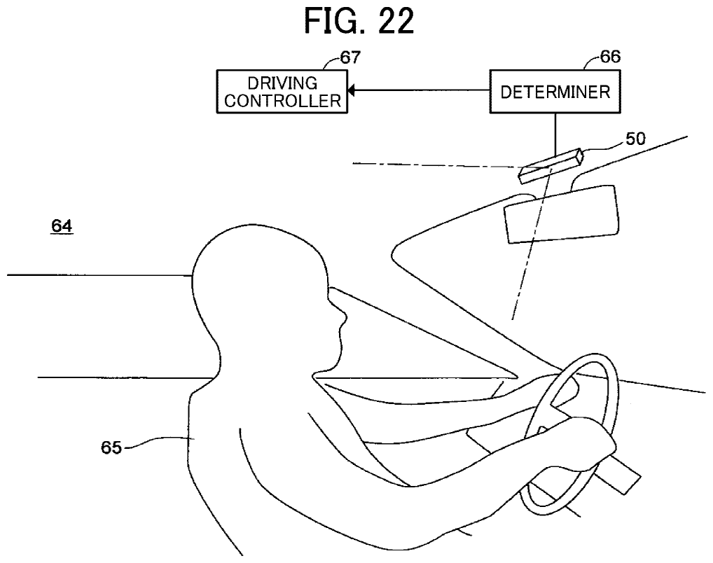

FIG. 22 illustrates an application example in which a detection device 50 is used in a driving assistance system of a mobile body such as an automobile. An automobile 64 has a driving assistance function that can automatically perform part of a driving operation, such as deceleration or steering. The driving assistance function may be implemented by dedicated hardware or may be implemented by execution of a program by an electronic control unit (ECU) that controls an electronic system of the automobile 64. The program may be stored in a memory such as a ROM.

The pattern light projector 13 of the detection device 50 mounted in the automobile 64 projects light to a driver 65 who drives the automobile 64. The three-dimensional measurer 15 of the detection device 50 receives light reflected by the driver 65 and the periphery of the driver 65 to perform image capturing. A determiner 66 determines information such as a face (facial expression) and a posture of the driver 65 based on image information obtained by image capturing the driver 65. Based on the determination result of the determiner 66, a driving controller 67 controls the brake and the steering wheel to perform appropriate driving assistance in accordance with the situation of the driver 65. For example, control on automatic deceleration or automatic stop can be performed when look-aside driving or falling-asleep driving is detected.

In the application example of FIG. 22, since the detection device 50 (pattern light projector 13) capable of projecting pattern light with which a plurality of cameras (first camera 25 and second camera 26) in the three-dimensional measurer 15 can easily recognize corresponding points is used, highly accurate three-dimensional information on the driver 65 can be obtained. In particular, since more information is obtained for the state of the driver 65 by projecting the pattern light, the accuracy of the driving assistance can be improved.

FIG. 22 illustrates the example in which the detection device 50 is mounted on the automobile 64; however, the detection device 50 can be applied to a train, an aircraft, or the like, as a mobile body other than an automobile. In addition to detecting the face and posture of a driver or a manipulator of a mobile body, the detection target can also be the state of a passenger in a passenger seat or the condition in a vehicle other than the passenger seat.

Similarly to the application example of FIG. 21, the function can be used for personal authentication for a driver. For example, the driver 65 is detected using the detection device 50 to permit the start of the engine when driver information matches to driver information registered in advance, or to permit locking and unlocking of the door lock.

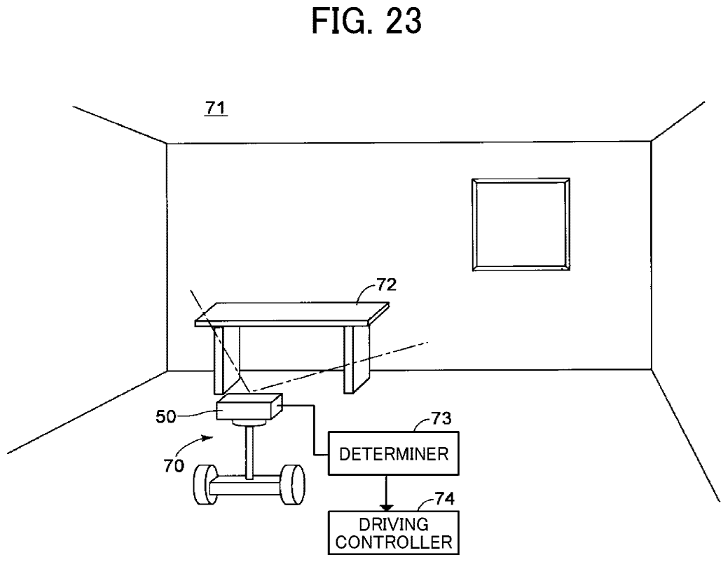

FIG. 23 illustrates an application example in which a detection device 50 is used in an autonomous traveling system in a mobile body. Unlike the application example of FIG. 22, in the application example of FIG. 23, the detection device 50 is used for sensing an object outside a mobile body 70. The mobile body 70 is an autonomous traveling mobile body capable of traveling automatically while recognizing an external situation. The detection device 50 is mounted on the mobile body 70. The detection device 50 emits light from a pattern light projector 13 in a traveling direction of the mobile body 70 and the peripheral region thereof. In a room 71 which is a moving area of the mobile body 70, a desk 72 is placed in the traveling direction of the mobile body 70. The three-dimensional measurer 15 of the detection device 50 receives and image captures light which is included in light projected from the pattern light projector 13 of the detection device 50 mounted on the mobile body 70 and which is reflected from the desk 72 and the periphery thereof. Based on captured image information or the like, information about the layout of the room 71, such as the distance to the desk 72, the position of the desk 72, and the surrounding condition other than the desk 72, is calculated. Based on the calculated information, a determiner 73 determines the moving path and the moving speed of the mobile body 70, and a driving controller 74 controls the traveling of the mobile body 70 (operation of the motor as a driving source, etc.) based on the determination result of the determiner 73.

In the application example of FIG. 23, since the detection device 50 (pattern light projector 13) capable of projecting pattern light with which a plurality of cameras (first camera 25 and second camera 26) in the three-dimensional measurer 15 can easily recognize corresponding points is used, highly accurate three-dimensional information on the room 71 can be obtained. In particular, by the projection with the pattern light, three-dimensional information can be reliably obtained even for a place where the contrast is low in the room 71. Thus, the accuracy of the autonomous traveling of the mobile body 70 can be improved.

FIG. 23 illustrates the example in which the detection device 50 is mounted on the autonomous traveling mobile body 70 that travels in the room 71; however, it can also be applied to an autonomous traveling vehicle (so-called automatic driving vehicle) that travels outdoors. Alternatively, the detection device 50 can be applied to the driving assistance system in a mobile body such as an automobile that a driver drives rather than autonomous traveling. In this case, the detection device 50 can be used to detect the surrounding condition of the mobile body, and to assist the driving of the driver in accordance with the detected surrounding condition.

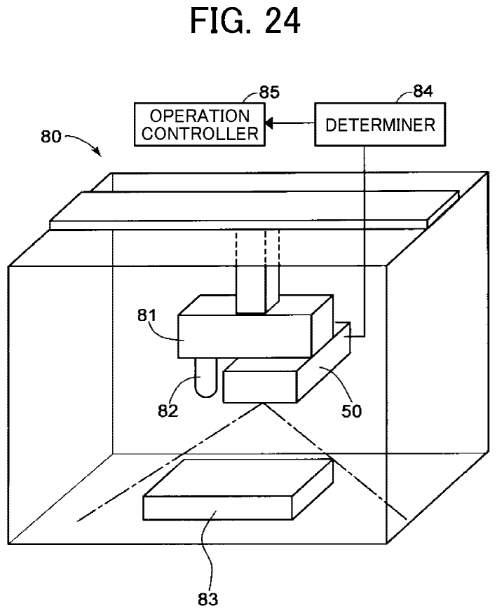

FIG. 24 illustrates an application example in which a detection device 50 is used in a three-dimensional (3D) printer 80 which is a shaping apparatus. The 3D printer 80 includes a head portion 81 including a nozzle 82. The nozzle 82 discharges a shaping liquid to form a shaped object 83. The detection device 50 is mounted on the head portion 81. The detection device 50 emits pattern light from the three-dimensional measurer 15 toward the shaped object 83 and the periphery thereof during formation of the shaped object 83. The detection device 50 receives reflected light from an irradiation region including the shaped object 83 using the three-dimensional measurer 15, performs image capturing, and generates image data. Based on obtained image information, a determiner 84 determines various kinds of information related to the shaped object 83 (the formed state of the shaped object 83). Based on the determination result, an operation controller 85 of the 3D printer 80 controls the movement of the head portion 81 and the discharge of the shaping liquid from the nozzle 82.

In the application example of FIG. 24, since the detection device 50 (pattern light projector 13) capable of projecting pattern light with which a plurality of cameras (first camera 25 and second camera 26) in the three-dimensional measurer 15 can easily recognize corresponding points is used, highly accurate three-dimensional information on the shaped object 83 can be obtained during the progress of the forming operation. In particular, by the projection with the pattern light, three-dimensional information can be reliably obtained even for a portion where the contrast is low in the shaped object 83. Thus, the shaped object 83 can be formed with high accuracy. In FIG. 24, the detection device 50 is mounted on the head portion 81 of the 3D printer 80; however, the detection device 50 may be mounted at another position of the 3D printer 80.

Although the embodiment of the present disclosure has been described above, the present disclosure is not limited to the above-described embodiment, and various modifications and changes can be made without departing from the spirit and scope of the disclosure.

Although the VCSEL is used as the light emitting element of the array light source 20 in the above embodiment, for example, an edge emitting laser may be used instead of the VCSEL. The VCSEL is advantageous in terms of easiness of providing a two-dimensional light emitting region and a high degree of freedom in arrangement of a plurality of light emitting regions. Even when a light source other than the VCSEL is used, an advantageous effect similar to that of the above-described embodiment can be obtained by setting the arrangement relationship of the plurality of light emitting elements and the positional relationship between each light emitting element and the microlens array.

The above-described embodiments are illustrative and do not limit the present invention. Thus, numerous additional modifications and variations are possible in light of the above teachings. For example, elements and/or features of different illustrative embodiments may be combined with each other and/or substituted for each other within the scope of the present invention.

1. An optical device comprising:
an array light source including a plurality of light emitting elements and configured to emit mutually incoherent light; and
a lens array including a plurality of lenses and configured to transmit light emitted from the light emitting elements,
wherein light emitted from one light emitting element of the plurality of light emitting elements of the array light source is incident on at least two lenses of the plurality of lenses of the lens array.

2. The optical device according to claim 1,
wherein the array light source includes the plurality of light emitting elements arranged in an uneven positional relationship.

3. The optical device according to claim 1,
wherein light emitted from the optical device includes light having different intensities.

4. The optical device according to claim 3,
wherein the array light source includes the plurality of light emitting elements configured to emit light having mutually different intensities.

5. The optical device according to claim 4,
wherein the array light source includes at least two electrode patterns to perform different electric control on the plurality of light emitting elements.

6. The optical device according to claim 4,
wherein the array light source includes the plurality of light emitting elements having mutually different emission areas.

7. The optical device according to claim 3,
wherein light with a first intensity obtained by superposition of light emitted from the plurality of light emitting elements, and light with a second intensity emitted from one light emitting element of the plurality of light emitting elements are generated.

8. The optical device according to claim 7,
wherein when the plurality of light emitting elements configured to emit light with the first intensity are arranged at an interval Δx which satisfies an expression as follows in at least one of a direction parallel to a lens arrangement axis of the lens array and a direction perpendicular to the lens arrangement axis,
$$Δ x = L tan θ = L tan ( {sin}^{- 1} \frac{λ}{t} ) = L \frac{( λ / t )}{\sqrt{1 - {( λ / t )}^{2}}}$$
where λ is an oscillation wavelength, t is a lens pitch of the lens array, and L is a light projection distance.

9. The optical device according to claim 1,
wherein the lens array includes the plurality of lenses arranged in one of a square arrangement, a rectangular arrangement, and a hexagonal arrangement.

10. The optical device according to claim 1,
wherein each of the plurality of light emitting elements is a vertical cavity surface emitting laser.

11. A detection device comprising:
the optical device according to claim 1; and
a detector configured to detect light emitted from the optical device and reflected by an object.

12. The detection device according to claim 11,
wherein the detector includes:
a plurality of imagers, and
wherein the detection device uses image information captured by each of the imagers, and parallax information on the plurality of imagers to acquire three-dimensional information on the object.

13. The detection device according to claim 12,
wherein a lens arrangement axis along which the plurality of lenses are arranged in the lens array is non-parallel to a pixel arrangement direction of an image sensor of each of the imagers.

14. An electronic apparatus comprising:
a determiner configured to receive information from the detection device according to claim 11 to make a determination based on the information; and
a controller configured to control an electrical signal based on the determination by the determiner.
